(19) United States
(12) Patent Application Publication
(10) Pub. No.: US 2018/0358204 A1
(43) Pub. Date: Dec. 13, 2018

(54) Plasma Strip Tool With Multiple Gas Injection Zones

(71) Applicant: Mattson Technology, Inc., Fremont, CA (US)

(72) Inventors: Shawming Ma, Sunnyvale, CA (US); Vladimir Nagorny, Tracy, CA (US); Dixit V. Desai, Pleasanton, CA (US); Ryan M. Pakulski, Discovery Bay, CA (US)

(21) Appl. No.: 15/892,723

(22) Filed: Feb. 9, 2018

Related U.S. Application Data
(60) Provisional application No. 62/610,582, filed on Dec. 27, 2017.
(60) Provisional application No. 62/517,365, filed on Jun. 9, 2017.

(51) Int. Cl. H01J 37/32; G03F 7/42

(52) U.S. Cl. CPC H01J 37/3244; H01J 37/32422; B08B 5/00; G03F 7/427; H01J 37/32357

(57) ABSTRACT

Plasma processing apparatus for processing a workpiece are provided. In one example embodiment, a plasma processing apparatus for processing workpiece includes a processing chamber, a plasma chamber separated from the processing chamber by a separation grid, an inductively coupled plasma source configured to generate a plasma in the plasma chamber. The apparatus includes a pedestal disposed within the processing chamber configured to support a workpiece. The apparatus a first gas injection zone configured to inject a process gas into the plasma chamber at a first flat surface, and a second gas injection zone configured to inject a process gas into the plasma chamber at a second flat surface. The separation grid has a plurality of holes configured to allow the passage of neutral particles generated in the plasma to the processing chamber.

### PRIORITY CLAIM

The present application claims the benefit of priority of U.S. Provisional Patent Application No. 62/610,582, entitled “Plasma Strip Tool With Multiple Gas Injection Zones,” filed on Dec. 27, 2017, which is incorporated herein by reference. The present application claims the benefit of priority of U.S. Provisional Application Ser. No. 62/517,365, titled “Plasma Strip Tool with Uniformity Control,” filed Jun. 9, 2017, which is incorporated herein by reference for all purposes.

### FIELD

The present disclosure relates generally to apparatuses, systems, and methods for processing a substrate using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates. Plasma strip tools can be used for strip processes, such as photoresist removal. Plasma strip tools can include a plasma chamber where plasma is generated and a separate processing chamber where the substrate is processed. The processing chamber can be “downstream” of the plasma chamber such that there is no direct exposure of the substrate to the plasma. A separation grid can be used to separate the processing chamber from the plasma chamber. The separation grid can be transparent to neutral species but not transparent to charged particles from the plasma. The separation grid can include a sheet of material with holes.

Uniformity control in plasma strip tools can be important for improved performance (e.g., improved ash rate performance). Uniformity can be difficult to tune in a plasma strip tool without manipulating process parameters, such gas pressure and flow, and RF power provided to induction coils used to generate the plasma.

### BRIEF DESCRIPTION

Aspects and advantages of the disclosed technology will be set forth in part in the following description, or may be obvious from the description, or may be learned through practice of the disclosure.

One example aspect of the present disclosure is directed to a plasma processing apparatus. The plasma processing apparatus includes a processing chamber, a plasma chamber separated from the processing chamber by a separation grid, an inductively coupled plasma source configured to generate a plasma in the plasma chamber, and a gas injection insert arranged in the plasma chamber. The gas injection insert has a peripheral portion and a center portion, the center portion extends a vertical distance past the peripheral portion. The apparatus includes a pedestal disposed within the processing chamber configured to support a semiconductor wafer. The apparatus includes a first gas injection zone configured to inject a process gas into the plasma chamber at a first flat surface. The apparatus includes a second gas injection zone configured to inject a process gas into the plasma chamber at a second flat surface. The separation grid has a plurality of holes configured to allow the passage of neutral particles generated in the plasma to the processing chamber.

These and other features, aspects and advantages of the disclosed technology will become better understood with reference to the following description and appended claims. The accompanying drawings, which are incorporated in and constitute a part of this specification, illustrate embodiments of the disclosed technology and, together with the description, serve to explain the principles of the disclosed technology.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma strip tool;

FIG. 2 depicts a portion of an example plasma strip tool according to example embodiments of the present disclosure;

FIG. 3 depicts a portion of an example plasma strip tool according to example embodiments of the present disclosure;

FIG. 4 depicts a portion of an example plasma strip tool according to example embodiments of the present disclosure;

FIG. 5 depicts a portion of an example plasma strip tool according to example embodiments of the present disclosure;

FIG. 6 depicts a portion of an example plasma strip tool according to example embodiments of the present disclosure;

FIG. 7 depicts a portion of an example separation grid according to example embodiments of the present disclosure; and

FIG. 8 depicts a portion of an example separation grid according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to uniformity control in plasma strip tools and plasma processing apparatuses. It is noted that the phrases “plasma strip tool” and “plasma processing apparatus,” including their plural forms, are used interchangeably herein. Example embodiments of the present disclosure can be used to provide uniformity tunability in a plasma strip tool using features that can provide for radial tunability.

Radial tunability can refer to tunability in a radial direction extending between a center portion of a workpiece processed in the plasma strip tool to a peripheral portion of a substrate processed in the plasma strip tool. According to example aspects of the present disclosure, radial tunability can be achieved, for instance, using multiple zone gas injection inside a plasma chamber and/or a processing chamber.

For example, in some embodiments, a plasma strip tool can include a plasma chamber that provides for multiple zone gas injection with each zone being located at a different flat surface inside the plasma chamber. For instance, a center gas zone can be provided at a first flat surface inside the plasma chamber proximate to a radial central portion of the plasma chamber and an edge gas zone can be provided at a second flat surface inside the plasma chamber at a radial edge portion of the plasma chamber. The same gas or different gas can be provided among the center gas zone and edge gas zone. More zones with gas injection at different flat surfaces inside the plasma chamber can be provided without deviating from the scope of the present disclosure, such as three zones, four zones, five zones, six zones, etc.

According to an example embodiment, a plasma processing apparatus for processing a workpiece is provided. The plasma processing apparatus can include a processing chamber, a plasma chamber separated from the processing chamber by a separation grid, and an inductively coupled plasma source configured to generate a plasma in the plasma chamber. The plasma processing apparatus can further include a pedestal disposed within the processing chamber, the pedestal configured to support a workpiece. Furthermore, the plasma processing apparatus can include a first gas injection zone configured to inject a process gas into the plasma chamber at a first flat surface and a second gas injection zone configured to inject a process gas into the plasma chamber at a second flat surface. The separation grid, according to this example embodiment, has a plurality of holes configured to allow the passage of neutral particles generated in the plasma to the processing chamber.

In some embodiments, the first flat surface is associated with a top plate of the plasma chamber and the second flat surface is associated with a center portion of a gas injection insert. In some embodiments, the gas injection insert can be arranged in the plasma chamber. The gas injection insert can have a peripheral portion and a center portion. The center portion can extend a vertical distance past the peripheral portion.

In some embodiments, the gas injection insert defines a gas injection channel proximate a side wall of the plasma chamber. In this example, the gas injection channel can be operative to feed gas into an active region defined by the flat surfaces, the gas injection insert, and the side wall. In some embodiments, the gas injection channel is operative to prevent plasma spreading within the plasma chamber.

In some embodiments, the plasma processing apparatus can also include a common gas source coupled to the first gas injection zone and the second gas injection zone. In some embodiments, a first gas source can be coupled to the first gas injection zone and a second gas source can be coupled to the second gas injection zone. In this example, the first and second gas sources can be two independent gas sources. Additionally, the first and second gas injection zones can also be configured to provide different gases to the plasma chamber.

In some embodiments, the separation grid has a gas injection aperture formed in a center portion of the separation grid. The gas injection aperture is configured to allow the injection of gas onto the workpiece. In this example, the gas injection aperture can be coaxially aligned with the center portion of the gas injection insert. In some embodiments, the gas injection aperture can also be directly coupled to a gas channel passing through the center portion of the gas injection insert. In some embodiments, the gas injection aperture can also be coupled to an independent gas source.

In some embodiments, the separation grid has a gas injection aperture formed in a peripheral portion of the separation grid. The gas injection aperture can be configured to allow the injection of gas onto the workpiece. In this example, the gas injection aperture can be coupled to an independent gas source.

In some embodiments, the separation grid has a first gas injection aperture formed in a center portion of the separation grid and a second gas injection aperture formed in a peripheral portion of the separation grid. The first gas injection aperture and the second gas injection aperture can be configured to allow the injection of gas onto the workpiece. In some embodiments, the first gas injection aperture and the second gas injection aperture can be coupled to a single gas source. In some embodiments, the first gas injection aperture and the second gas injection aperture can also be coupled to independent gas sources.

Another example embodiment is directed to a plasma processing apparatus for processing a workpiece. The plasma processing apparatus can include a processing chamber, a plasma chamber separated from the processing chamber by a separation grid, and an inductively coupled plasma source configured to generate a plasma in the plasma chamber. The plasma processing apparatus can also include a pedestal disposed within the processing chamber. The pedestal is configured to support a workpiece. The separation grid has a first gas injection aperture formed in a center portion of the separation grid and a second gas injection aperture formed in a peripheral portion of the separation grid. The first gas injection aperture and the second gas injection aperture are configured to allow the injection of gas onto the workpiece.

In some embodiments, the first gas injection aperture and the second gas injection aperture can be coupled to a single gas source. In some embodiments, the first gas injection aperture and the second gas injection aperture can also be coupled to independent gas sources.

Aspects of the present disclosure are discussed with reference to a “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within 10% of the stated numerical value. The use of the term “pedestal” can refer to any structure operable to support a workpiece during processing.

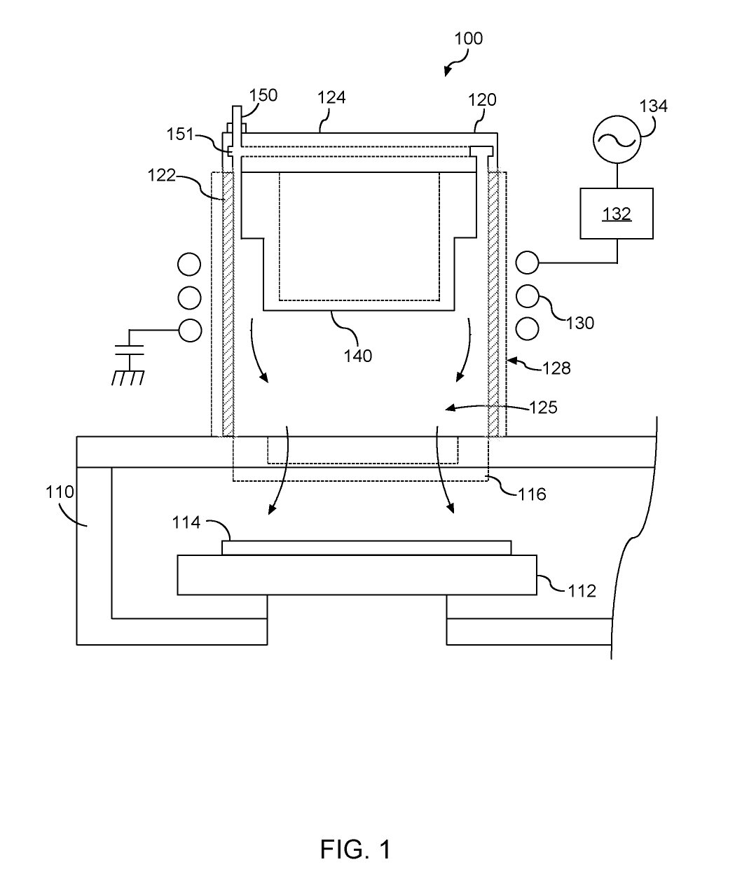

With reference now to the drawings, example embodiments of the present disclosure will now be set forth. FIG. 1 depicts an example plasma strip tool 100. The strip tool 100 includes a processing chamber 110 and a plasma chamber 120 that is separate from the processing chamber 110. The processing chamber 110 includes a substrate holder or pedestal 112 operable to hold a substrate 114. An inductive plasma can be generated in plasma chamber 120 (i.e., plasma generation region) and desired particles are then channeled from the plasma chamber 120 to the surface of substrate 114 through holes provided in a grid 116 that separates the plasma chamber 120 from the processing chamber 110 (i.e., downstream region).

The separation grid may include a plurality of holes, perforations, channels, or other openings to allow a flow of particles from the plasma chamber 120 to the processing chamber 110. The particles are used to process the semiconductor substrate as described herein. For example, the separation grid 116 may separate charged ions from the plasma and allow passage of other particles onto the semiconductor wafer. The separation grid can be formed of any suitable material.

The plasma chamber 120 can also include a dielectric side wall 122 and a ceiling 124. The dielectric side wall 122 and ceiling 124 define a plasma chamber interior 125. The dielectric side wall 122 can be formed from any dielectric material, such as quartz. The ceiling 124 can also be termed a “top plate.”

An induction coil 130 can be disposed adjacent the dielectric side wall 122 about the plasma chamber 120. The induction coil 130 can be coupled to an RF power generator 134 through a suitable matching network 132. The induction coil 130 can be formed of any suitable material, including conductive materials suitable for inducing plasma within the plasma chamber 120. For example, reactant and carrier gases can be provided to the chamber interior from gas supply 150. When the induction coil 130 is energized with RF power from the RF power generator 134, a substantially inductive plasma is induced in the plasma chamber 120. In a particular embodiment, the plasma strip tool 100 can include a grounded Faraday shield 128 to reduce capacitive coupling of the induction coil 130 to the plasma. The grounded Faraday shield 128 can be formed of any suitable material or conductor, including materials similar or substantially similar to the induction coil 130.

To increase efficiency, the plasma strip tool 100 can include a gas injection insert 140 disposed in the chamber interior 125. The gas injection insert 140 can be removably inserted into the chamber interior 125 or can be a fixed part of the plasma chamber 120. The gas injection insert 140 can also include or define one or more gas injection channels as described below.

In some embodiments, the gas injection insert 140 can define a gas injection channel proximate the side wall of the plasma chamber. The gas injection channel can feed a process gas into the chamber interior proximate the induction coil 130 and into an active region defined by the gas injection insert 140 and side wall 122. The active region provides a confined region within the plasma chamber interior for active heating of electrons.

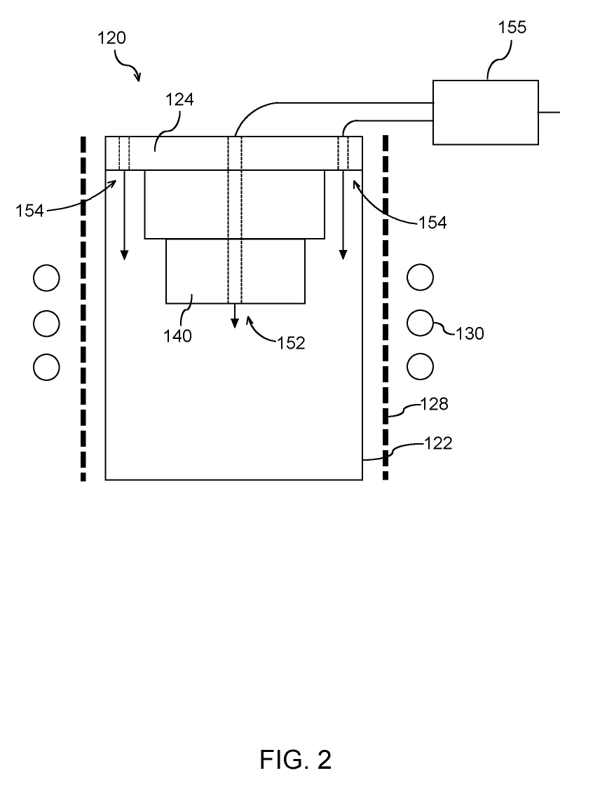

According to one implementation, the gas injection channel is relatively narrow. The narrow gas injection channel prevents plasma spreading from the chamber interior into the gas channel. The gas injection insert 140 can also force the process gas to be passed through the active region where electrons are actively heated. Various features for improving uniformity of a strip tool or plasma processing apparatus, such as strip tool 100, will now be set forth with reference to FIGS. 2-6.

FIG. 2 depicts a portion of an example plasma strip tool according to example embodiments of the present disclosure. As shown, the strip tool includes multiple gas injection zones at different flat portions (e.g., flat surfaces) in the plasma chamber 120.

For instance, in FIG. 2, a center gas injection zone 152 is located on a flat surface of the insert 140. An edge gas injection zone 154 is located on a flat surface of the top plate 124. A gas splitter 155 can be used to split a process gas (e.g., the same gas combination) from a common gas source among the center gas injection zone 152 and the edge gas injection zone 154. In some example embodiments, independent gas sources can be used to feed multiple gas injection zones.

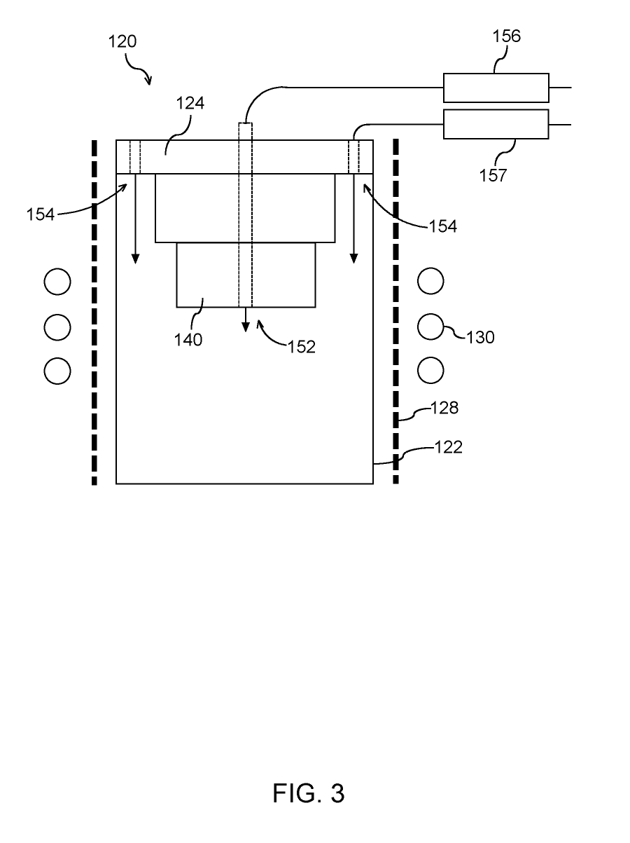

FIG. 3 depicts a portion of an example plasma strip tool according to example embodiments of the present disclosure. As shown, the strip tool includes multiple gas injection zones at different flat portions (e.g., flat surfaces) in the plasma chamber 120. For instance, a center gas injection zone 152 is located on a flat surface of the insert 140. An edge gas injection zone 154 is located on a flat surface of the top plate 124. The center gas injection zone 152 can have an independent gas source 156. The edge gas injection zone 154 can have an independent gas source 157. The same or different gases or gas combinations can be provided to the center gas injection zone 152 and the edge gas injection zone 154. Although illustrated as having single gas injection openings associated with different gas injection zones, according to some example embodiments, multiple gas injection openings can be associated with one or more of the gas injection zones.

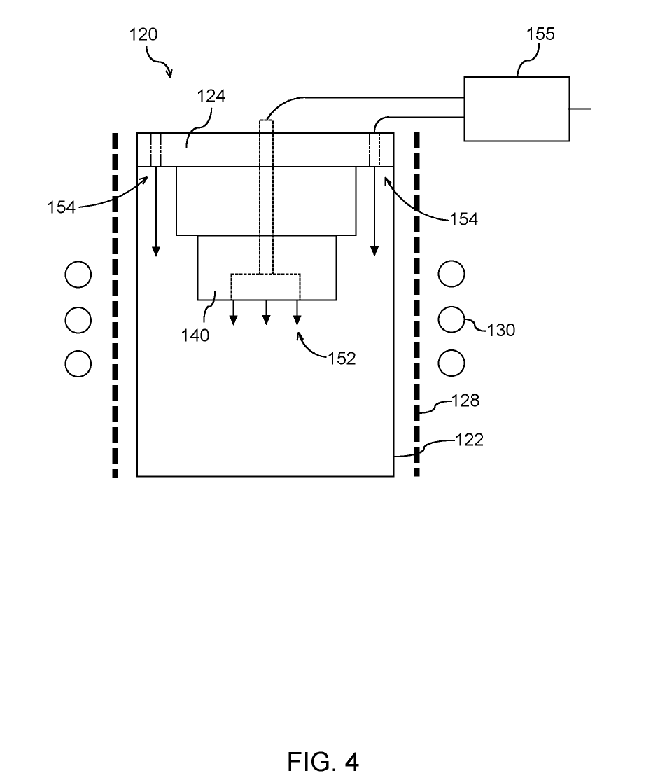

FIG. 4 depicts a portion of an example plasma strip tool according to example embodiments of the present disclosure. As shown, the strip tool includes multiple gas injection zones at different flat portions (e.g., flat surfaces) in the plasma chamber 120. For instance, a center gas injection zone 152 is located on a flat surface of the insert 140. An edge gas injection zone 154 is located on a flat surface of the top plate 124. A gas splitter 155 can be used to split a process gas (e.g., the same gas combination) among the center gas injection zone 152 and the edge gas injection zone 154. Multiple gas injection openings can be provided at the center gas injection zone 152. In some example embodiments, neutral gas injection zones can be associated with the separation grid 116, to provide gas to the processing chamber 110 and/or substrate 114.

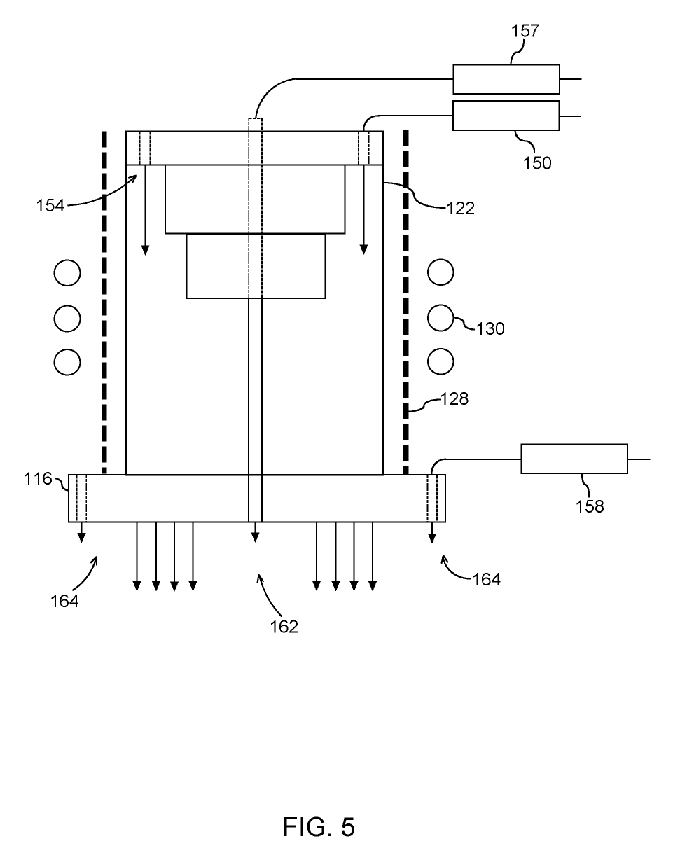

FIG. 5 depicts a portion of an example plasma strip tool according to example embodiments of the present disclosure. As shown, the plasma strip tool includes a center gas injection aperture 162 in a central portion of the separation grid 116. The plasma strip tool includes an edge gas injection aperture 164 at an edge portion of the separation grid 116. The center gas injection aperture 162 can have an independent gas source 157. The edge gas injection zone 164 can have an independent gas source 158. The same or different gases or gas combinations can be provided to the center gas injection aperture 162 and the edge gas injection zone 164. A neutral gas (e.g., nitrogen, helium, argon) can be injected onto the workpiece via apertures 162 and/or 164.

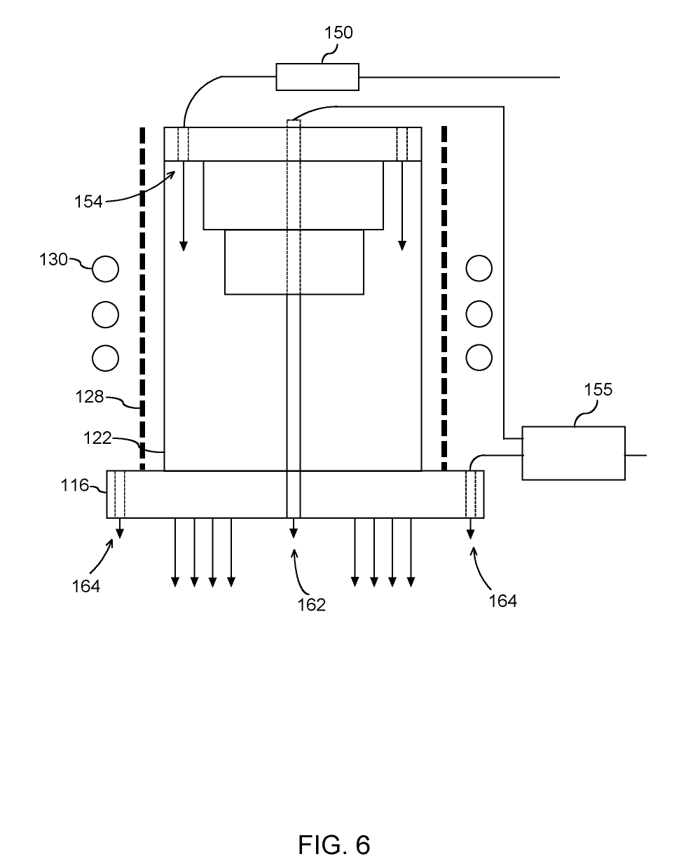

FIG. 6 depicts a portion of an additional example plasma strip tool according to example embodiments of the present disclosure. The plasma strip tool includes a center gas injection aperture 162 in a central portion of the separation grid 116. The plasma strip tool includes an edge gas injection aperture 164 at an edge portion of the separation grid 116. A gas splitter 155 can be used to split a gas (e.g., the same gas combination) from a common gas source among the center gas injection aperture 162 and the edge gas injection aperture 164.

As described above, several example embodiments of plasma processing apparatus have been described in detail. The plasma processing apparatuses can include multiple gas injection zones configured to increase uniformity in plasma processing of substrates, such as semiconductor wafers. Each gas injection zone of the multiple gas injection zones can include an independent gas source, can share a gas source, or can include multiple combinations of the same. For example, two gas injection zones can share a first gas source while a third gas injection zone is coupled to a different gas source. Additionally, a plurality of different gases and associated sources can be combined as described and illustrated herein.

The plasma processing apparatuses can also include gas injection zones/apertures at a separation grid and configured to provide a gas (e.g., neutral gas) to a workpiece. The gas injection zones can be fed by gas sources. Furthermore, each gas injection zone can include a different gas source or can share a common gas source. These and other implementations are considered to be within the scope of example embodiments.

Aspects of the present disclosure are discussed with reference to two different gas injection zones to control radial uniformity for example purposes. Multiple gas injection zones, such as three gas injection zones, four gas injection zones, five gas injection zones, etc. can be used without deviating from the scope of the present disclosure.

The zones can also be used to provide for other uniformity control, such as azimuthal uniformity. For instance, in some embodiments, the plasma processing apparatus can include a plurality of gas injection zones arranged to inject gas at flat surfaces in the plasma chamber at different azimuthal positions within the plasma chamber. In some embodiments, the plasma processing apparatus can include a plurality of gas injection zones arranged to inject gas onto a workpiece from different azimuthal portions of the separation grid.

The gas injection zones are illustrated as injecting gas in a vertical direction for purposes of illustration and discussion. Those of ordinary skill in the art will understand that the gas injection zones can inject gas in any direction. For instance, the gas injection zones can inject gas in a vertical, horizontal, or oblique directions.

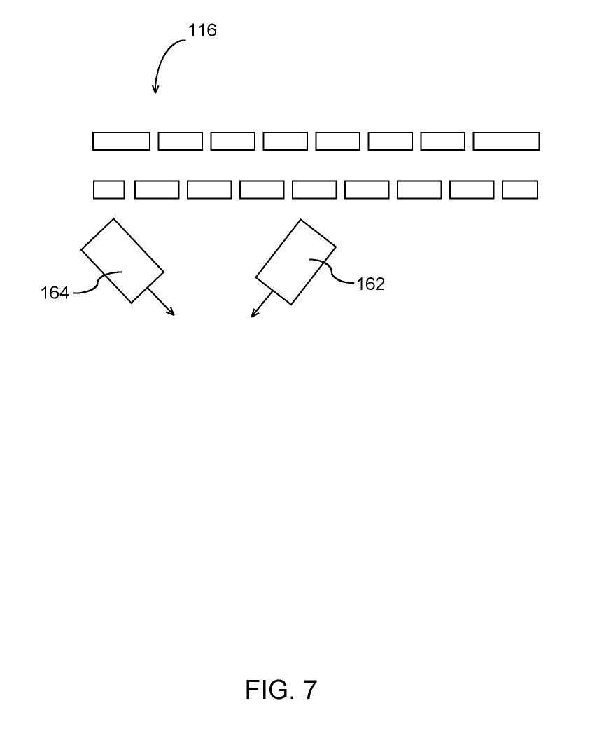

As an example, FIG. 7 illustrates a separation grid 116 with a center gas injection aperture 162 in a central portion of the separation grid 116. The separation grid 116 includes an edge gas injection aperture 164 at an edge portion of the separation grid 116. The center gas injection aperture 162 can inject gas in a direction that is different than the edge gas injection aperture. 164. For instance, the center gas injection aperture 162 can inject gas in a first oblique direction. The edge gas injection aperture 164 can inject gas in a second oblique direction.

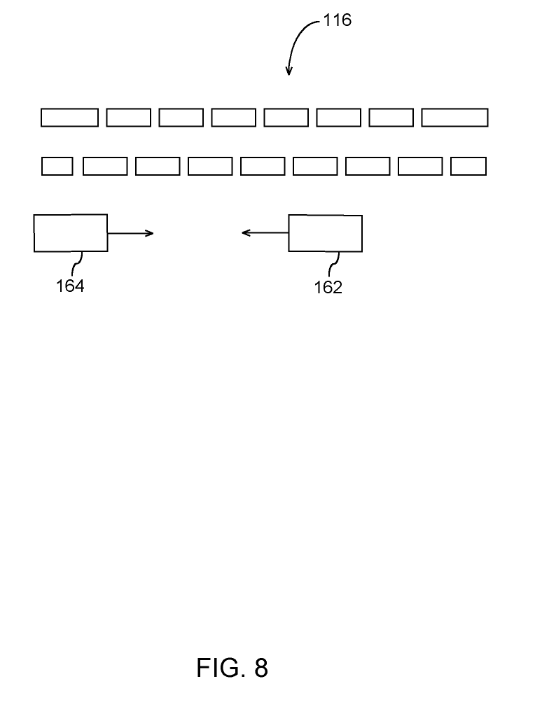

As an example, FIG. 8 illustrates a separation grid 116 with a center gas injection aperture 162 in a central portion of the separation grid 116. The separation grid 116 includes an edge gas injection aperture 164 at an edge portion of the separation grid 116. The center gas injection aperture 162 can inject gas in a direction that is different than the edge gas injection aperture. 164. For instance, the center gas injection aperture 162 can inject gas in a first horizontal direction. The edge gas injection aperture 164 can inject gas in a second horizontal direction.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus for processing a workpiece, the plasma processing apparatus comprising:
a processing chamber;
a plasma chamber separated from the processing chamber by a separation grid;
an inductively coupled plasma source configured to generate a plasma in the plasma chamber;
a pedestal disposed within the processing chamber, the pedestal configured to support a workpiece;
a first gas injection zone configured to inject a process gas into the plasma chamber at a first flat surface; and
a second gas injection zone configured to inject a process gas into the plasma chamber at a second flat surface;
wherein the separation grid has a plurality of holes configured to allow the passage of neutral particles generated in the plasma to the processing chamber.

2. The plasma processing apparatus of claim 1, wherein the first flat surface is associated with a top plate of the plasma chamber and the second flat surface is associated with a gas injection insert disposed within the plasma chamber.

3. The plasma processing apparatus of claim 2, wherein the gas injection insert has a peripheral portion and a center portion, the center portion extending a vertical distance past the peripheral portion

4. The plasma processing apparatus of claim 1, further comprising a common gas source coupled to the first gas injection zone and the second gas injection zone.

5. The plasma processing apparatus of claim 1, further comprising a first gas source coupled to the first gas injection zone and a second gas source coupled to the second gas injection zone.

6. The plasma processing apparatus of claim 1, wherein the first and second gas injection zones are operable to provide different gases to the plasma chamber.

7. The plasma processing apparatus of claim 3, wherein the gas injection insert defines a gas injection channel proximate a side wall of the plasma chamber.

8. The plasma processing apparatus of claim 1, wherein the separation grid has a gas injection aperture formed in a center portion of the separation grid, the gas injection aperture configured to allow the injection of gas onto the workpiece.

9. The plasma processing apparatus of claim 8, wherein the gas injection aperture is coaxially aligned with the center portion of the gas injection insert.

10. The plasma processing apparatus of claim 8, wherein the gas injection aperture is coupled to a gas channel passing through a center portion of a gas injection insert.

11. The plasma processing apparatus of claim 8, wherein the gas injection aperture is coupled to an independent gas source.

12. The plasma processing apparatus of claim 1, wherein the separation grid has a gas injection aperture formed in a peripheral portion of the separation grid, the gas injection aperture configured to allow the injection of gas onto the workpiece

13. The plasma processing apparatus of claim 12, wherein the gas injection aperture is coupled to an independent gas source.

14. The plasma processing apparatus of claim 1, wherein the separation grid has a first gas injection aperture formed in a center portion of the separation grid and a second gas injection aperture formed in a peripheral portion of the separation grid, the first gas injection aperture and the second gas injection aperture configured to allow the injection of gas onto workpiece.

15. The plasma processing apparatus of claim 14, wherein the first gas injection aperture and the second gas injection aperture are coupled to a common gas source.

16. The plasma processing apparatus of claim 14, wherein the first gas injection aperture and the second gas injection aperture are coupled to independent gas sources.

17. A plasma processing apparatus for processing workpiece, the plasma processing apparatus comprising:
a processing chamber;
a plasma chamber separated from the processing chamber by a separation grid;
an inductively coupled plasma source configured to generate a plasma in the plasma chamber;
a pedestal disposed within the processing chamber, the pedestal configured to support a workpiece;
wherein the plasma processing apparatus comprises a first gas injection aperture formed in a center portion of the separation grid and a second gas injection aperture formed in a peripheral portion of the separation grid, the first gas injection aperture and the second gas injection aperture configured to allow the injection of gas onto the workpiece.

18. The plasma processing apparatus of claim 17, wherein the gas injection aperture is coupled to a gas channel passing through a center portion of a gas injection insert.

19. The plasma processing apparatus of claim 17, wherein the first gas injection aperture and the second gas injection aperture are coupled to a common gas source.

20. The plasma processing apparatus of claim 17, wherein the first gas injection aperture and the second gas injection aperture are coupled to independent gas sources.
